(19) United States
(12) Patent Application Publication
(10) Pub. No.: US 2026/0198106 A1
(43) Pub. Date: Jul. 9, 2026

(54) ION DETECTION DEVICE

(71) Applicant: SHANGHAI TIANMA MICROELECTRONICS CO., LTD., Shanghai (CN)

(72) Inventors: Linzhi WANG, Shanghai (CN); Kaidi ZHANG, Shanghai (CN); Baiquan LIN, Shanghai (CN)

(73) Assignee: SHANGHAI TIANMA MICROELECTRONICS CO., LTD., Shanghai (CN)

(21) Appl. No.: 19/553,849

(22) Filed: Mar. 2, 2026

(30) Foreign Application Priority Data
Oct. 15, 2025 (CN) 202511478125.X

(51) Int. Cl. H10F 30/298; G01T 1/24

(52) U.S. Cl. CPC H10F 30/298; G01T 1/24

(57) ABSTRACT

Provided is an ion detection device. The ion detection device includes a substrate, a circuit layer, an ion-sensitive layer, an encapsulation layer, and a blocking layer. The circuit layer is located on a side of the substrate and includes a first transistor. The ion-sensitive layer is located on a side of the circuit layer facing away from the substrate. The encapsulation layer is located on a side of the ion-sensitive layer facing away from the substrate and is provided with a first through hole that exposes part of the ion-sensitive layer. The blocking layer is located between the circuit layer and the ion-sensitive layer and includes a first blocking portion that overlaps the first through hole in a direction perpendicular to a plane on which the substrate is located.

### CROSS-REFERENCE TO RELATED APPLICATION

This application claims priority to Chinese patent application No. 202511478125.X filed with the China National Intellectual Property Administration (CNIPA) on Oct. 15, 2025, the disclosure of which is incorporated herein by reference in its entirety.

### TECHNICAL FIELD

The present disclosure relates to the technical field of ion detection and, in particular, to an ion detection device.

### BACKGROUND

An ion detection device based on a transistor (such as a thin-film transistor) may convert an ion concentration signal into a measurable electrical signal by changing key electrical parameters of the transistor (such as a threshold voltage, channel conductivity, or a source-drain current) through specific interactions between an ion-sensitive layer and to-be-detected ions, thereby enabling miniaturized, highly integrated, and low-power ion detection.

However, existing ion detection devices suffer from reliability problems due to the permeation of testing solutions into regions where internal transistors are located, which leads to the failure of the devices.

### SUMMARY

The present disclosure provides an ion detection device.

The ion detection device provided in the present disclosure includes a substrate, a circuit layer, an ion-sensitive layer, an encapsulation layer, and a blocking layer.

The circuit layer is located on a side of the substrate and includes a first transistor.

The ion-sensitive layer is located on a side of the circuit layer facing away from the substrate.

The encapsulation layer is located on a side of the ion-sensitive layer facing away from the substrate and is provided with a first through hole, and the first through hole exposes part of the ion-sensitive layer.

The blocking layer is located between the circuit layer and the ion-sensitive layer and includes a first blocking portion, and the first blocking portion overlaps the first through hole in a direction perpendicular to a plane on which the substrate is located.

It is to be understood that the content described in this section is neither intended to identify key or critical features of the embodiments of the present disclosure nor intended to limit the scope of the present disclosure. Other features of the present disclosure become easily understood through the description provided below.

### BRIEF DESCRIPTION OF DRAWINGS

To illustrate the technical solutions in the embodiments of the present disclosure more clearly, drawings used in the description of the embodiments are briefly described below. Apparently, the drawings described below illustrate part of the embodiments of the present disclosure, and those of ordinary skill in the art may obtain other drawings based on the drawings described below on the premise that no creative work is done.

FIG. 1 is a structural diagram of an ion detection device according to an embodiment of the present disclosure.

FIG. 2 is another structural diagram of an ion detection device according to an embodiment of the present disclosure.

FIG. 3 is another structural diagram of an ion detection device according to an embodiment of the present disclosure.

FIG. 4 is another structural diagram of an ion detection device according to an embodiment of the present disclosure.

FIG. 5 is another structural diagram of an ion detection device according to an embodiment of the present disclosure.

FIG. 6 is another structural diagram of an ion detection device according to an embodiment of the present disclosure.

FIG. 7 is another structural diagram of an ion detection device according to an embodiment of the present disclosure.

FIG. 8 is another structural diagram of an ion detection device according to an embodiment of the present disclosure.

FIG. 9 is another structural diagram of an ion detection device according to an embodiment of the present disclosure.

FIG. 10 is another structural diagram of an ion detection device according to an embodiment of the present disclosure.

FIG. 11 is another structural diagram of an ion detection device according to an embodiment of the present disclosure.

FIG. 12 is another structural diagram of an ion detection device according to an embodiment of the present disclosure.

FIG. 13 is another structural diagram of an ion detection device according to an embodiment of the present disclosure.

FIG. 14 is another structural diagram of an ion detection device according to an embodiment of the present disclosure.

FIG. 15 is another structural diagram of an ion detection device according to an embodiment of the present disclosure.

### DETAILED DESCRIPTION

To make the technical solutions of the present disclosure better understood by those skilled in the art, the technical solutions in the embodiments of the present disclosure are described below clearly and completely in conjunction with the drawings in the embodiments of the present disclosure. Apparently, the embodiments described below are part, not all, of embodiments of the present disclosure. Based on the embodiments of the present disclosure, all other embodiments obtained by those of ordinary skill in the art are within the scope of the present disclosure on the premise that no creative work is done.

It is apparent for those skilled in the art that various modifications and variations can be made in the present disclosure without departing from the spirit or scope of the present disclosure. Accordingly, the present disclosure is intended to cover modifications and variations of the present disclosure that fall within the scope of the appended claims (the claimed technical solutions) and their equivalents. It is to be noted that embodiments of the present disclosure, if not in collision, may be combined with one another.

First, it is to be noted that, unless otherwise defined, technical terms or scientific terms used in the present disclosure shall have general meanings understood by those with general skills in the field to which the present disclosure belongs. The terms "first", "second", and the like in the present disclosure are used to distinguish between different components but not used to describe any order, quantity, or significance. The term "including" and the like means that the elements or objects in front of the term cover elements or objects and their equivalents listed in the back of the term, but do not exclude other elements or objects. The term "connected", "joined", or the like is not limited to a physical or mechanical connection, but may include an electrical connection, whether it is direct or indirect. "Up", "down", "left", "right", and the like are used for indicating a relative positional relationship, and when the absolute position of a described object is changed, the relative positional relationship may also change accordingly. In addition, the shape and size of each component in the drawings do not reflect the real scale, and the purpose is only to illustrate the content of the present disclosure.

An existing ion detection device typically includes a substrate, and a transistor, an ion-sensitive layer, and an encapsulation layer that are sequentially stacked on a side of the substrate from bottom to top. The encapsulation layer is provided with a through hole for exposing the ion-sensitive layer, allowing a testing solution to contact the ion-sensitive layer through the through hole. Consequently, ion detection may be enabled through a cascaded response mechanism of the sensing of to-be-detected ions by the ion-sensitive layer and electrical parameters of the transistor. In the conventional detection device, the through hole formed in the encapsulation layer usually overlaps the projection of the transistor along a thickness direction of the device, for example, overlaps a channel region of the transistor. As a result, during detection, the testing solution may permeate through the ion-sensitive layer and a dielectric layer above the transistor to reach a layer in which the transistor is located, thereby causing a reliability problem and leading to the failure of the device. For example, the testing solution may corrode the transistor, resulting in the failure of the device; or a source and a drain of the transistor may form an electrical path with the testing solution, leading to leakage current of the device or a short circuit of the device.

To address these problems, the present disclosure provides an ion detection device. The ion detection device includes a substrate, a circuit layer, an ion-sensitive layer, an encapsulation layer, and a blocking layer. The circuit layer is located on a side of the substrate and includes a first transistor. The ion-sensitive layer is located on the side of the circuit layer facing away from the substrate. The encapsulation layer is located on one side of the ion-sensitive layer facing away from the substrate and is provided with a first through hole that exposes part of the ion-sensitive layer. The blocking layer is located between the circuit layer and the ion-sensitive layer and includes a first blocking portion that overlaps the first through hole in a direction perpendicular to a plane on which the substrate is located.

With the preceding solutions adopted, since the blocking layer is disposed between the ion-sensitive layer and the circuit layer and includes the first blocking portion overlapping the first through hole, the blocking layer can be used to block at least part of a solution that continues penetrating toward a side of the substrate from the first through hole, thereby mitigating or even avoiding the adverse effects of the testing solution on the first transistor and enhancing the reliability of the device.

The preceding is the core idea of the present disclosure. Technical solutions in embodiments of the present disclosure are described clearly and completely in conjunction with the drawings in the embodiments of the present disclosure. Based on the embodiments of the present disclosure, all other embodiments obtained by those of ordinary skill in the art are within the scope of the present disclosure on the premise that no creative work is done.

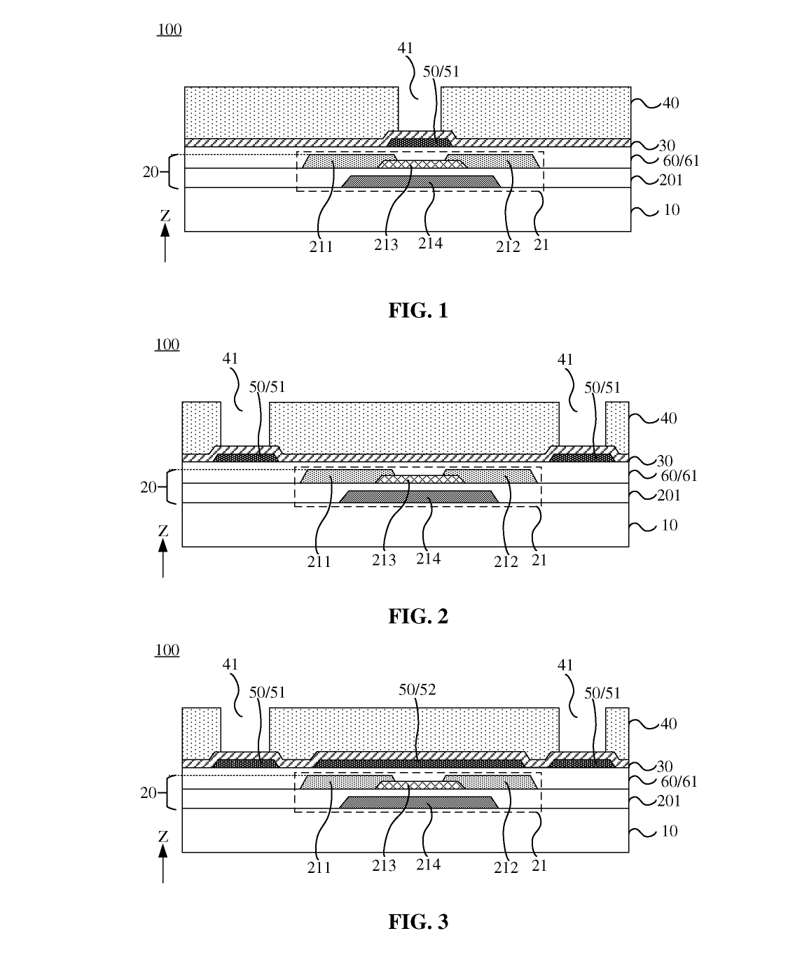

FIG. 1 is a structural diagram of an ion detection device according to an embodiment of the present disclosure. As shown in FIG. 1, the ion detection device 100 provided in the embodiment of the present disclosure includes a substrate 10, a circuit layer 20, an ion-sensitive layer 30, an encapsulation layer 40, and a blocking layer 50. The circuit layer 20 is located on a side of the substrate 10 and includes a first transistor 21. The ion-sensitive layer 30 is located on a side of the circuit layer 20 facing away from the substrate 10. The encapsulation layer 40 is located on a side of the ion-sensitive layer 30 facing away from the substrate 10 and is provided with a first through hole 41 that exposes part of the ion-sensitive layer 30. The blocking layer 50 is located between the circuit layer 20 and the ion-sensitive layer 30 and includes a first blocking portion 51 that overlaps the first through hole 41 in a direction Z perpendicular to a plane on which the substrate 10 is located.

The first transistor 21 refers to a transistor in the circuit layer 20 that is configured to output a corresponding electrical signal in response to an ion sensing signal (which is manifested that a voltage/charge on the ion-sensitive layer 30 varies with the concentration of the ions) of to-be-detected ions by the ion-sensitive layer 30. In one or more embodiments, the first transistor 21 is a thin-film transistor. In addition to the first transistor 21, the circuit layer 20 may further include other electronic elements, which may be configured as needed by those skilled in the art and are not limited in the embodiment of the present disclosure. The circuit layer 20 may be understood as a layer in which the first transistor 21 and the other electronic elements are located.

The ion-sensitive layer 30 has ion sensitivity. The material of the ion-sensitive layer 30 is not limited in the embodiment of the present disclosure, as long as factors such as ion selectivity, stability, compatibility with a semiconductor process, and detection sensitivity are taken into account. In one or more embodiments, when the to-be-detected ions are Cl ions, the material of the ion-sensitive layer 30 may include, but is not limited to, AgCl; when the to-be-detected ions are Na ions, the material of the ion-sensitive layer 30 may include, but is not limited to, β-AlO₃; when the to-be-detected ions are Cu ions, the material of the ion-sensitive layer 30 may include, but is not limited to, ZnO; when the to-be-detected ions are H ions, the material of the ion-sensitive layer 30 may include, but is not limited to, SnO₂; and when the to-be-detected ions are ammonium ions, the material of the ion-sensitive layer 30 may include, but is not limited to, graphene and a two-dimensional material (such as molybdenum disulfide).

The encapsulation layer 40 is provided with the first through hole 41 through which a testing solution may come into contact with the ion-sensitive layer 30. Consequently, the ion detection is enabled through a cascaded response mechanism between the sensing of the to-be-detected ions by the ion-sensitive layer and electrical parameters of the transistor.

In this embodiment, the encapsulation layer 40 may be a single layer or may also be formed by stacking multiple layers, which is not limited in the embodiment of the present disclosure. The material of the encapsulation layer 40 should have low permeability to provide a sealing effect, thereby ensuring the performance and service life of the device. The material of the encapsulation layer 40 is not limited in the embodiment of the present disclosure.

It is to be noted that the encapsulation layer 40 may be provided with one, two, or even more first through holes 41, which is not limited in the embodiment of the present disclosure. FIG. 1 shows an example in which the encapsulation layer 40 is provided with a single first through hole 41.

In one or more embodiments, in this embodiment, the blocking layer 50 is also provided between the ion-sensitive layer 30 and the circuit layer 20. Moreover, the blocking layer 50 includes the first blocking portion 51 that overlaps the first through hole 41 in the direction perpendicular to the plane on which the substrate 10 is located.

The blocking layer 50 is configured to prevent the testing solution from continuing to penetrate toward the substrate 10. Compared with a non-through-hole region (that is, a region except for the through hole) of the encapsulation layer 40, the testing solution more easily continues penetrating into a lower layer through the first through hole 41. In this embodiment, the blocking layer 50 is disposed between the ion-sensitive layer 30 and the circuit layer 20 and includes the first blocking portion 51 corresponding to the first through hole 41 so that the first blocking portion 51 and the first through hole 41 are arranged to overlap along the direction Z perpendicular to the plane on which the substrate 10 is located. In this manner, the first blocking portion 51 can be used to block at least part of the solution that continues penetrating toward a side of the substrate from the first through hole 41, thereby mitigating the adverse effects of the testing solution on the first transistor and enhancing the reliability of the device.

In one or more embodiments, the material of the blocking layer 50 includes metal. The metal has good density, which can ensure effective blocking of the solution and thereby enhance the reliability of the device. In one or more embodiments, the material of the blocking layer 50 may include, but is not limited to, copper, aluminum, or silver.

Referring to FIG. 1, in one or more embodiments, the orthographic projection of the first blocking portion 51 on the substrate 10 covers the orthographic projection of the first through hole 41 on the substrate 10.

In one or more embodiments, the preceding projection coverage relationship may be understood as follows: the area of the orthographic projection of the first blocking portion 51 on the substrate 10 is greater than the area of the orthographic projection of the first through hole 41 on the substrate 10, and the boundary of the orthographic projection of the first blocking portion 51 on the substrate 10 is located outside the boundary of the orthographic projection of the first through hole 41 on the substrate 10. In other words, the boundary of the orthographic projection of the first blocking portion 51 on the substrate 10 completely surrounds the boundary of the orthographic projection of the first through hole 41 on the substrate 10. In this manner, the first blocking portion 51 can be used to prevent the testing solution from continuing to penetrate toward the substrate 10 from the first through hole 41, thereby preventing the testing solution from damaging the first transistor 21 and affecting the reliability of the device.

Referring to FIG. 1, in one or more embodiments, the first transistor 21 includes a source 211 and a drain 212, and the ion detection device 100 further includes a first dielectric layer 61. The first dielectric layer 61 covers the source 211 and the drain 212. The blocking layer 50 is located on the side of the first dielectric layer 61 facing away from the substrate 10.

Referring to FIG. 1, the first transistor 21 further includes an active layer 213. The source 211 and the drain 212 are located on the side of the active layer 213 facing away from the substrate 10, and each of the source 211 and the drain 212 forms an ohmic contact with the active layer 213. One of the source 211 and the drain 212 serves as a signal output terminal of the first transistor 21.

The first dielectric layer 61 specifically refers to a dielectric layer located on the side of the first transistor 21 facing away from the substrate 10 and covering the source 211 and the drain 212. As shown in FIG. 1, the first dielectric layer 61 is in contact with the source 211 and the drain 212, and covers a side surface and a top surface of the source 211 and a side surface and a top surface of the drain 212. In this embodiment, the blocking layer 50 is located on the side of the first dielectric layer 61 facing away from the substrate 10. This arrangement can reduce adjustments to the preparation process and ensure a high yield.

In conclusion, in the embodiment of the present disclosure, the blocking layer is disposed between the ion-sensitive layer and the circuit layer and includes the first blocking portion corresponding to the first through hole so that the first blocking portion and the first through hole are arranged to overlap in the direction perpendicular to the plane on which the substrate is located. In this manner, the first blocking portion can be used to block at least part of the solution that continues penetrating toward the side of the substrate from the first through hole, thereby mitigating or even avoiding the adverse effects of the testing solution on the first transistor and enhancing the reliability of the device.

Referring to FIG. 1, in one or more embodiments, the first through hole 41 overlaps a channel region of the first transistor 21.

The channel region refers to a portion of the active layer 213 that is located between the source 211 and the drain 212. The first through hole 41 overlaps the channel region of the first transistor 21 so that a path through which the ion sensing signal of the to-be-detected ions on the ion-sensitive layer 30 acts on the active layer of the first transistor can be shortened, thereby ensuring the detection sensitivity. In this embodiment, the first blocking portion 51 can be used to prevent the testing solution from penetrating toward one side adjacent to the substrate 10 from the first through hole 41, thereby preventing the testing solution from damaging the active layer 213 of the first transistor 21.

In one or more embodiments, referring to FIG. 1, when the first through hole 41 overlaps the channel region of the first transistor 21, the first blocking portion 51 also overlaps the channel region of the first transistor 21. In this case, the blocking layer 50 needs to have conductivity to ensure that the ion sensing signal on the ion-sensitive layer 30 can act on the first transistor through the blocking layer 50, thereby enabling the ion detection.

Referring to FIG. 1, the first transistor 21 includes the source 211 and the drain 212. In one or more embodiments, the first through hole 41 does not overlap at least one of the source 211 or the drain 212 in the direction Z perpendicular to the plane on which the substrate 10 is located.

In one or more embodiments, the orthographic projection of the first through hole 41 on the substrate 10 does not intersect the orthographic projection of the source 211 on the substrate 10, and/or the orthographic projection of the first through hole 41 on the substrate 10 does not intersect the orthographic projection of the drain 212 on the substrate 10. In this manner, a region in which the first through hole 41 is formed can be kept away from at least one of the source 211 or the drain 212. On one hand, the blocking layer 50 can be used to prevent the testing solution from penetrating into a lower layer; on the other hand, the first through hole 41 is kept away from a region in which the source 211 is located and/or a region in which the drain 212 is located so that the risk of a short circuit between the source 211 and the drain 212 through the testing solution can be further reduced, thereby improving the reliability of the device.

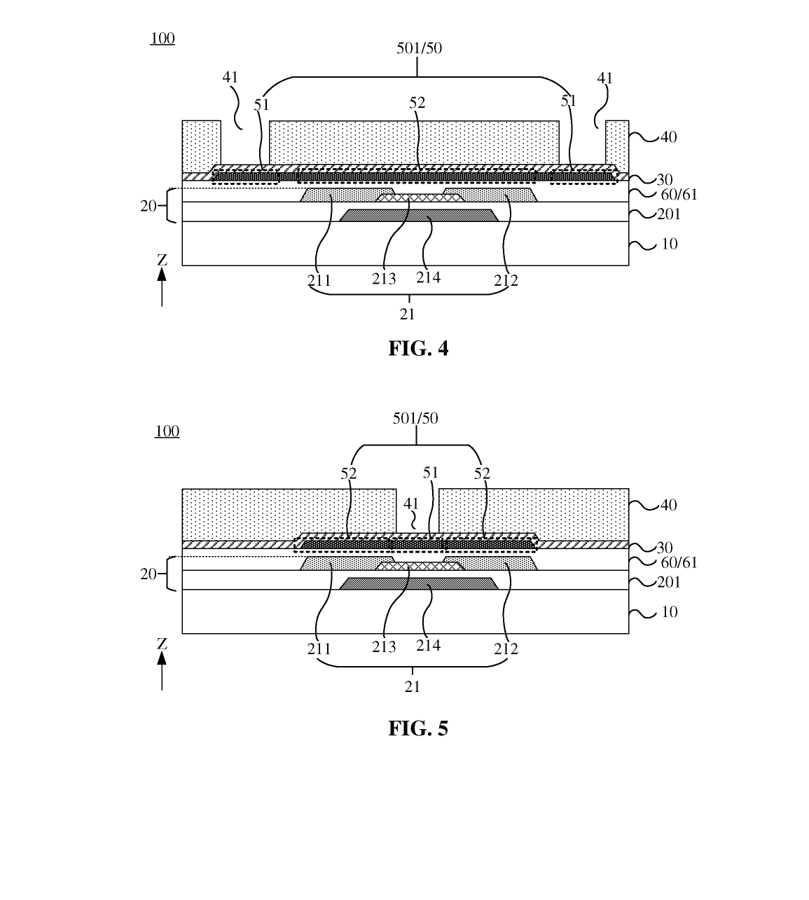

FIG. 2 is another structural diagram of an ion detection device according to an embodiment of the present disclosure. As shown in FIG. 2, in one or more embodiments, the first through hole 41 does not overlap the first transistor 21 in the direction Z perpendicular to the plane on which the substrate 10 is located. In other words, the orthographic projection of the first through hole 41 on the substrate 10 does not intersect the orthographic projection of the first transistor 21 on the substrate 10. In this manner, the region in which the first through hole 41 is formed can be kept away from the first transistor 21. On one hand, the blocking layer 50 can be used to prevent the testing solution from penetrating into the lower layer; on the other hand, the first through hole 41 is kept away from a region in which the first transistor 21 is located so that the risk of the testing solution damaging the first transistor 21 can be further reduced, thereby enhancing the reliability of the device.

The orthographic projection of the preceding first transistor 21 on the substrate 10 may be understood as a combined region of orthographic projections of structures of various layers of the first transistor 21 on the substrate 10. Referring to FIG. 2, using the first transistor 21 including the source 211, the drain 212, the active layer 213, and a first gate 214 as an example, the orthographic projection of the first transistor 21 on the substrate 10 refers to the combined region of the orthographic projections of the source 211, the drain 212, the active layer 213, and the first gate 214 on the substrate 10.

Referring to FIG. 2, in one or more embodiments, the first blocking portion 51 does not overlap the first transistor 21. In this case, the ion-sensitive layer 30 may be extended to the region in which the first transistor 21 is located so that the ion-sensitive layer 30 overlaps the channel region of the first transistor 21 in the direction Z perpendicular to the plane on which the substrate 10 is located, thereby ensuring that the ion sensing signal can act on the first transistor 21 to achieve the ion detection.

Referring to FIG. 2, it is to be noted that, in this example, since the blocking layer 50 does not overlap the first transistor 21, the blocking layer 50 may not have conductivity. In addition to the metallic material, other materials capable of effectively preventing the solution from penetrating may also be selected, which is not limited in the embodiment of the present disclosure.

FIG. 3 is another structural diagram of an ion detection device according to an embodiment of the present disclosure. As shown in FIG. 3, in one or more embodiments, the blocking layer 50 further includes a second blocking portion 52 that overlaps the first transistor 21 in the direction Z perpendicular to the plane on which the substrate 10 is located.

The difference between the second blocking portion 52 and the first blocking portion 51 lies in that, along the direction Z perpendicular to the plane on which the substrate 10 is located, the second blocking portion 52 does not overlap the first through hole 41, but instead overlaps the first transistor 21.

There is also a possibility that, in the non-through-hole region of the encapsulation layer 40, the testing solution may permeate into a layer in which the first transistor 21 is located. In this embodiment, the blocking layer 50 further includes the second blocking portion 52, and the second blocking portion 52 overlaps the first transistor 21 so that the second blocking portion 52 can be used to protect at least part of the first transistor 21, thereby further reducing the reliability problems of the device caused by the permeation of the solution.

In one or more embodiments, FIG. 3 shows an example in which the first through hole 41 does not overlap the first transistor 21 in the direction Z perpendicular to the plane on which the substrate 10 is located. In this case, the first blocking portion 51 is disposed corresponding to the first through hole 41 to block the testing solution from continuing permeating toward the substrate 10 from the first through hole 41, and the second blocking portion 52 is disposed corresponding to the first transistor 21 to block the testing solution from permeating toward the substrate 10 from the non-through-hole region of the encapsulation layer 40. In this manner, the first transistor 21 can be protected, further enhancing the reliability of the device. Referring to FIG. 3, in one or more embodiments, the second blocking portion 52 overlaps the source 211 of the first transistor 21, the drain 212 of the first transistor 21, and the active layer 213 of the first transistor 21 in the direction Z perpendicular to the plane on which the substrate 10 is located, thereby providing comprehensive protection for the first transistor 21.

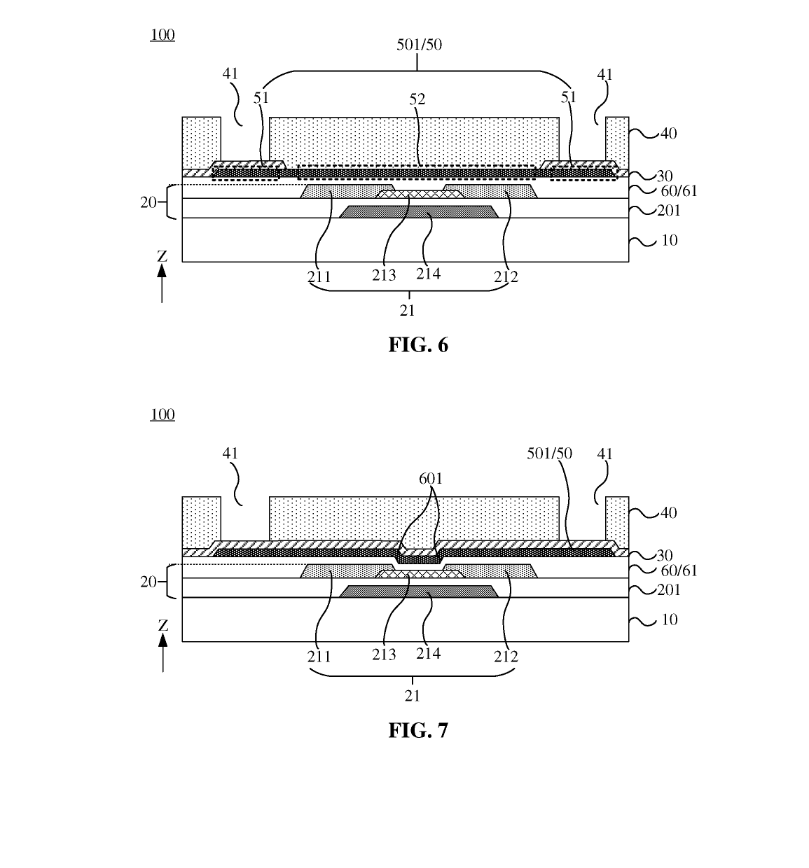

FIG. 4 is another structural diagram of an ion detection device according to an embodiment of the present disclosure. As shown in FIG. 4, in one or more embodiments, the blocking layer 50 includes a blocking structure 501, and the blocking structure 501 includes the first blocking portion 51 and the second blocking portion 52 that are connected to each other.

In one or more embodiments, the first blocking portion 51 and the second blocking portion 52 are connected to each other to form an integrated structure, that is, the blocking structure 501. In this manner, the difficulty in the patterning process of the blocking layer can be reduced, thereby reducing the precision requirements for a corresponding mask and ensuring product yield.

With continued reference to FIG. 4, in one or more embodiments, the orthographic projection of the blocking structure 501 on the substrate 10 covers the orthographic projection of the first transistor 21 on the substrate 10.

In one or more embodiments, the orthographic projection of the blocking structure 501 on the substrate 10 should at least cover the orthographic projection of the first transistor 21 on the substrate 10. In this manner, the blocking structure 501 can provide comprehensive protection for the first transistor 21.

Referring to FIG. 4, when the first through hole 41 does not overlap the first transistor 21, the orthographic projection of the blocking structure 501 on the substrate 10 not only covers the orthographic projection of the first transistor 21 on the substrate 10, but also overlaps the orthographic projection of the first through hole 41 on the substrate 10. FIG. 4 shows an example in which the orthographic projection of the blocking structure 501 on the substrate 10 covers both the orthographic projection of the first transistor 21 on the substrate 10 and the orthographic projection of the first through hole 41 on the substrate 10. In this case, the blocking structure 501 can not only block the testing solution from penetrating into the lower layer from the first through hole 41 but also provide comprehensive protection for the first transistor 21. Moreover, since the first through hole 41 does not overlap the first transistor 21, even if a small amount of the solution penetrates into the first through hole 41 after long-term operation of the device, it is unlikely to adversely affect the first transistor 21, thereby effectively ensuring the reliability and service life of the device.

FIG. 5 is another structural diagram of an ion detection device according to an embodiment of the present disclosure. As shown in FIG. 5, in one or more embodiments, the first through hole 41 overlaps the channel region of the first transistor 21, and the orthographic projection of the blocking structure 501 on the substrate 10 covers the orthographic projection of the first transistor 21 on the substrate 10. In this manner, the blocking structure 501 can also be used to block the testing solution from penetrating into the lower layer from the first through hole 41 and provide comprehensive protection for the first transistor 21.

According to the preceding explanation, when the orthographic projection of the blocking structure 501 on the substrate 10 covers the orthographic projection of the first transistor 21 on the substrate 10, the blocking layer 50 should have conductivity. For example, a conductive metal may be selected to simultaneously provide conductivity and layer compactness, thereby enabling the ion detection and blocking the testing solution from penetrating into the lower layer.

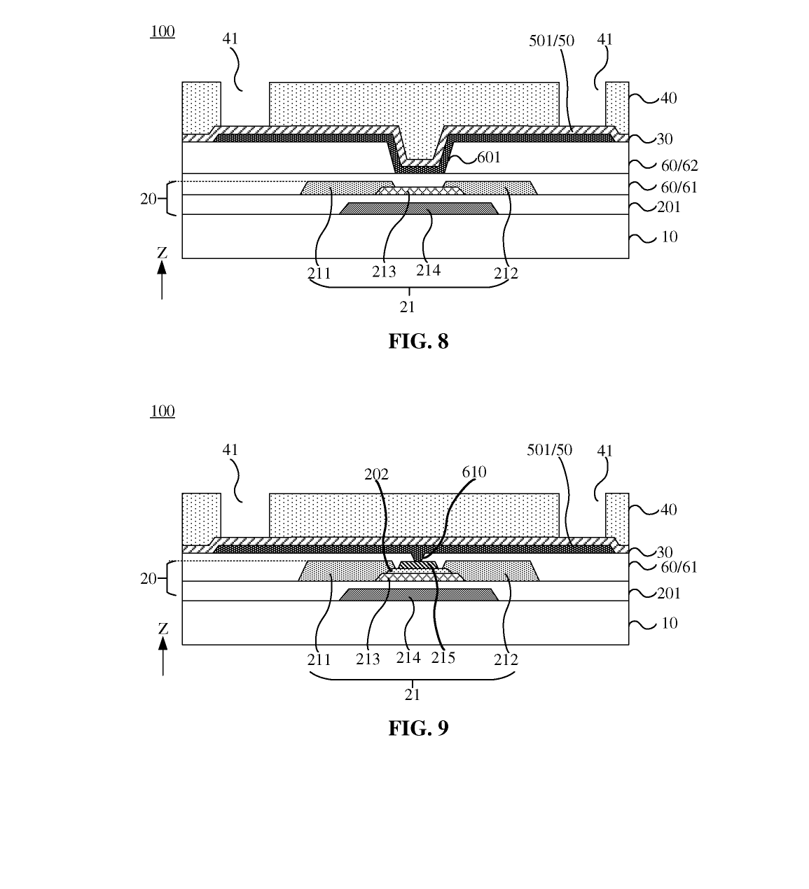

It is to be noted that the preceding embodiments are all illustrated using an example in which the ion-sensitive layer 30 overlaps the channel region of the first transistor 21. FIG. 6 is another structural diagram of an ion detection device according to an embodiment of the present disclosure. As shown in FIG. 6, in other embodiments, when the first through hole 41 does not overlap the first transistor 21 in the direction Z perpendicular to the plane on which the substrate 10 is located, the orthographic projection of the blocking structure 501 on the substrate 10 covers the orthographic projection of the first transistor 21 on the substrate 10, and the ion-sensitive layer 30 does not overlap the first transistor 21 in the direction Z perpendicular to the plane on which the substrate 10 is located. In this case, the ion sensing signal on the ion-sensitive layer 30 can act on the first transistor 21 through the blocking structure 501, thereby enabling the ion detection.

FIG. 7 is another structural diagram of an ion detection device according to an embodiment of the present disclosure. As shown in FIG. 7, in one or more embodiments, the ion detection device 100 further includes a dielectric layer 60 that is located between the first transistor 21 and the blocking layer 50, and the dielectric layer 60 is formed with a first groove 601 that overlaps the channel region of the first transistor 21 in the direction Z perpendicular to the plane on which the substrate 10 is located.

As shown in FIG. 7, the first transistor includes the source 211 and the drain 212 that are disposed in the same layer. The dielectric layer 60 is located between the first transistor 21 and the blocking layer 50, which may mean that the dielectric layer 60 is located between the source 211 and the blocking layer 50 or between the drain 212 and the blocking layer 50.

One or more dielectric layers 60 may be provided, and the first groove 601 may be formed in at least one of these dielectric layers. Since the dielectric layer 60 is located on the side of the blocking layer 50 facing the first transistor 21, and the first groove 601 overlaps the channel region of the first transistor 21 in the direction Z perpendicular to the plane on which the substrate 10 is located, the formation of the first groove 601 in the dielectric layer 60 can shorten the distance between the blocking structure 501 and the channel region of the first transistor 21, thereby enhancing the detection sensitivity.

In one or more embodiments, FIG. 7 shows an example in which the dielectric layer 60 includes the first dielectric layer 61 covering the source 211 and the drain 212. As shown in FIG. 7, the first dielectric layer 61 is formed with the first groove 601, and the depth of the first groove 601 is less than the thickness of the first dielectric layer 61, that is, the first groove 601 does not penetrate through the first dielectric layer 61. The formation of the first groove 601 in the first dielectric layer 61 corresponding to the channel region of the first transistor 21 can shorten the distance between the blocking structure 501 and the channel region of the first transistor 21, thereby enhancing the detection sensitivity.

FIG. 8 is another structural diagram of an ion detection device according to an embodiment of the present disclosure. As shown in FIG. 8, in one or more embodiments, the dielectric layer 60 includes the first dielectric layer 61 and a second dielectric layer 62, and the second dielectric layer 62 is located between the first dielectric layer 61 and the blocking layer 50; the thickness of the second dielectric layer 62 is greater than that of the first dielectric layer 61, and the first groove 601 is located in the second dielectric layer 62.

In one or more embodiments, the second dielectric layer 62 is added on the side of the first dielectric layer 61 facing away from the substrate 10, the thickness of the second dielectric layer 62 is greater than the thickness of the first dielectric layer 61, and the first groove 601 is formed in the second dielectric layer 62. In this manner, by increasing the number and thickness of dielectric layers above the first transistor 21, the difficulty for the testing solution to penetrate into the layer in which the first transistor 21 is located can be further increased, thereby enhancing the reliability of the device. Compared with forming the groove in the first dielectric layer 61, forming the first groove 601 in the second dielectric layer 62 in this embodiment can ensure a small distance between the blocking structure 501 and the channel region of the first transistor 21, thereby reducing the process precision requirements while ensuring the detection sensitivity. In this manner, the first dielectric layer 61 can be used to protect the first transistor 21 below the first dielectric layer 61, thereby preventing damage to the first transistor 21 due to over-etching during the preparation of the first groove 601.

As shown in FIG. 8, in one or more embodiments, the first groove 601 penetrates through the second dielectric layer 62. In this manner, the small distance between the blocking structure 501 and the channel region of the first transistor 21 can be ensured, thereby enhancing the detection sensitivity. Certainly, this configuration is not limited. In other embodiments, provided that the detection sensitivity satisfies the requirements, the first groove 601 may also not penetrate through the second dielectric layer 62.

In one or more embodiments, the material of the first dielectric layer 61 includes, but is not limited to, SiN, and the material of the second dielectric layer 62 includes, but is not limited to, SiN and an organic resin material. In one or more embodiments, the thickness of the first dielectric layer 61 ranges from 1,000 angstroms to 3,000 angstroms, and the thickness of the second dielectric layer 62 only needs to be greater than that of the first dielectric layer 61.

In one or more embodiments, the first transistor 21 includes the source 211 and the drain 212, and the first groove 601 does not overlap the source 211 and the drain 212 in the direction Z perpendicular to the plane on which the substrate 10 is located.

In one or more embodiments, the orthographic projection of the first groove 601 on the substrate 10 does not intersect the orthographic projection of the source 211 on the substrate 10 and the orthographic projection of the drain 212 on the substrate 10, and only overlaps the channel region of the first transistor 21. This configuration ensures that the second dielectric layer isolates the source 211 from the testing solution and isolates the drain 212 from the testing solution, thereby guaranteeing the reliability of the device.

It is to be noted that the preceding embodiments are illustrated using an example in which the first transistor 21 includes a single gate (the first gate 214). In one or more embodiments, the first gate 214 is located between the active layer 213 and the substrate 10, and a first gate insulating layer 201 is disposed between the first gate 214 and the active layer 213. In this case, in one or more embodiments, at least part of the blocking structure 501 is in contact with the first dielectric layer 61. For example, FIGS. 6 and 7 show an example in which the entire blocking structure 501 is in contact with the first dielectric layer 61, while FIG. 8 shows an example in which part of the blocking structure 501 is in contact with the first dielectric layer 61 through the first groove 601.

FIG. 9 is another structural diagram of an ion detection device according to an embodiment of the present disclosure. As shown in FIG. 9, in one or more embodiments, the first transistor 21 includes the first gate 214, the active layer 213, and a second gate 215; the first gate 214 is located between the substrate 10 and the active layer 213, and the second gate 215 is located on the side of the active layer 213 facing away from the substrate 10; the ion detection device 100 further includes the dielectric layer 60 that is located between the second gate 215 and the blocking layer 50; the dielectric layer 60 includes a first via 610 through which the blocking structure 501 is electrically connected to the second gate 215.

In one or more embodiments, in this embodiment, the first transistor 21 is a dual-gate transistor having both a bottom gate and a top gate, that is, the first gate 214 and the second gate 215. The first gate insulating layer 201 is disposed between the first gate 214 and the active layer 213, and a second gate insulating layer 202 is disposed between the second gate 215 and the active layer 213. The second gate insulating layer 202 exposes a source region of the active layer 213 and a drain region of the active layer 213 so that the source 211 is in contact with the source region of the active layer 213, the drain 212 is in contact with the drain region of the active layer 213, and the second gate 215 is insulated from both the source 211 and the drain 212.

The first gate 214 is used to control the first transistor 21 to turn on and off, and the second gate 215 is used to receive the ion sensing signal, enabling the first transistor 21 to output the electrical signal in response to the ion sensing signal. In one or more embodiments, the second gate 215 is electrically connected to the blocking structure 501 through the first via 610 in the upper dielectric layer 60, thereby receiving the ion sensing signal.

In an embodiment, an etch stop layer (ESL) may be used as the second gate insulating layer. The etch stop layer is thinner than an insulating layer formed by a conventional gate insulating layer and a conventional passivation layer. In this manner, capacitive coupling amplification can be enabled, thereby enhancing ion response sensitivity of the device.

As described in the preceding, one or more dielectric layers may be provided between the first transistor 21 and the blocking layer 50. Regardless of the number of dielectric layers 60, the first via 610 overlaps the second gate 215 along the direction Z perpendicular to the plane on which the substrate 10 is located, and penetrates through one or more dielectric layers between the second gate 215 and the blocking structure 501, thereby electrically connecting the blocking structure 501 to the second gate 215.

In one or more embodiments, FIG. 9 shows an example in which one dielectric layer 60, such as the first dielectric layer 61, is provided between the first transistor 21 and the blocking layer 50. In this case, the first via 610 is located in the first dielectric layer 61 and penetrates through a portion of the first dielectric layer 61 that is located between the second gate 215 and the blocking structure 501, thereby electrically connecting the second gate 215 to the blocking structure 501 through the first via 610.

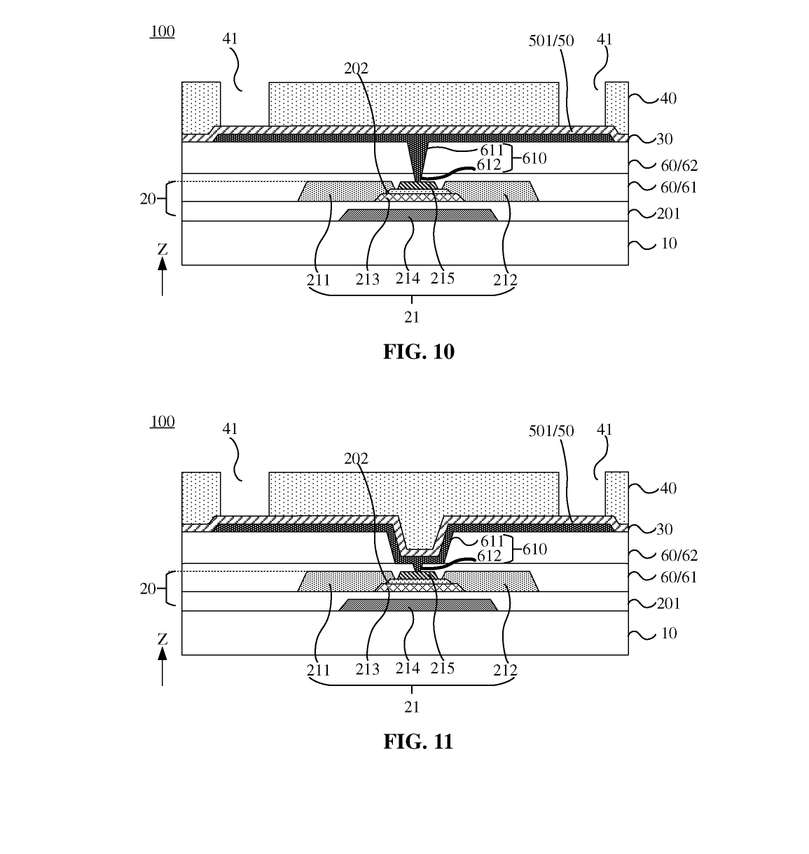

FIG. 10 is another structural diagram of an ion detection device according to an embodiment of the present disclosure. As shown in FIG. 10, in one or more embodiments, the dielectric layer 60 includes the first dielectric layer 61 and the second dielectric layer 62, and the second dielectric layer 62 is located on the side of the first dielectric layer 61 facing away from the substrate 10. In this case, for example, the first via 610 includes a first sub-via 611 and a second sub-via 612 that are connected to each other. The first sub-via 611 is located in the second dielectric layer 62 and penetrates through the second dielectric layer 62. The second sub-via 612 is located in the first dielectric layer 61 and penetrates through a portion of the first dielectric layer 61 that is located between the second gate 215 and the second dielectric layer 62. In this manner, the second gate 215 is electrically connected to the blocking structure 501 through the first via 610. As shown in FIG. 10, in one or more embodiments, the sidewall of the first sub-via 611 and the sidewall of the second sub-via 612 are smoothly connected (without any steps).

FIG. 11 is another structural diagram of an ion detection device according to an embodiment of the present disclosure. As shown in FIG. 11, in one or more embodiments, the aperture of the first sub-via 611 is greater than the aperture of the second sub-via 612, and a stepped surface is formed between the inner wall of the first sub-via 611 and the inner wall of the second sub-via 612. For example, part of a top surface of the first dielectric layer 61 forms the preceding stepped surface. In an example, in this embodiment, the first sub-via 611 may be designed with reference to the preceding first groove 601.

Based on any of the preceding embodiments, referring to FIG. 11, in one or more embodiments, the ion-sensitive layer 30 is in direct contact with the blocking layer 50.

In one or more embodiments, the ion-sensitive layer 30 and the blocking layer 50 are adjacent layers, with no other layers, such as a dielectric layer, disposed between them. In this manner, the number of layers in the ion detection device is not excessively increased, which is conducive to a thinner design of the device. In addition, when the blocking layer 50 covers the channel region of the first transistor 21, the ion-sensitive layer 30 in direct contact with the blocking layer 50 can help ensure a large contact area between the ion-sensitive layer 30 and the blocking layer 50, thereby ensuring the sensitivity of the device.

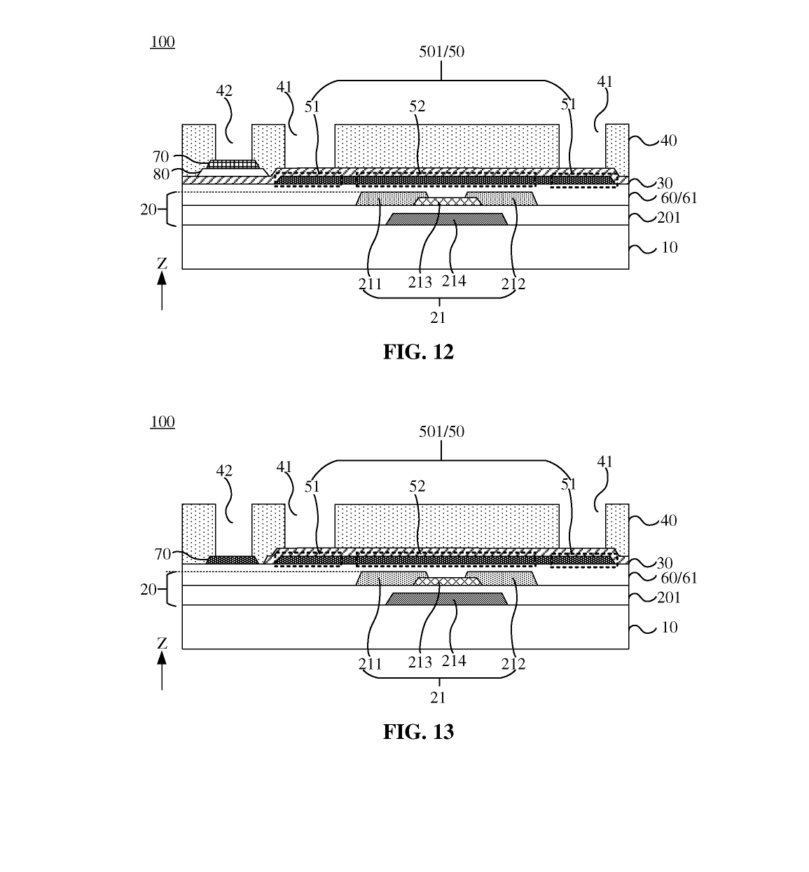

FIG. 12 is another structural diagram of an ion detection device according to an embodiment of the present disclosure. As shown in FIG. 12, in one or more embodiments, the ion detection device 100 further includes a reference electrode 70 located on the side of the circuit layer 20 facing away from the substrate 10, and the encapsulation layer 40 is further provided with a second through hole 42 that exposes part of the reference electrode 70.

A fixed potential is applied to the reference electrode 70 to provide a known and stable potential reference for the ion detection device, thereby ensuring the accuracy and reliability of a detection result.

As shown in FIG. 12, the reference electrode 70 is insulated from both the ion-sensitive layer 30 and the blocking layer 50. During ion detection, the reference electrode 70 may be in contact with the testing solution through the second through hole 42. In this embodiment, both the ion-sensitive layer and the reference electrode 70 are provided in the ion detection device 100 so that the integration of the device can be enhanced. In other embodiments, the ion-sensitive layer and the reference electrode may also be disposed in different devices, which is not limited in the embodiment of the present disclosure.

Two feasible configurations for the reference electrode 70 are provided below.

As a feasible configuration, referring to FIG. 12, in one or more embodiments, the reference electrode 70 overlaps the ion-sensitive layer 30 in the direction Z perpendicular to the plane on which the substrate 10 is located; the ion detection device 100 further includes a first insulating layer 80 located between the reference electrode 70 and the ion-sensitive layer 30.

In this embodiment, by forming the first insulating layer 80 on the side of the ion-sensitive layer 30 facing away from the substrate 10, insulation between the reference electrode 70 and the ion-sensitive layer 30 is enabled using the first insulating layer 80. This configuration features a simple process and does not require any modification to the existing pattern design of the ion-sensitive layer 30.

Referring to FIG. 12, in one or more embodiments, the first insulating layer 80 does not overlap the first through hole 41 in the direction Z perpendicular to the plane on which the substrate 10 is located. In other words, the termination position of the first insulating layer 80 is located in the non-through-hole region of the encapsulation layer 40 and does not extend to a region in which the first through hole 41 is located. When overlapping the first through hole 41, the first insulating layer 80 would shield part of the ion-sensitive layer 30 in the region in which the first through hole 41 is located, thereby reducing the exposed area of the ion-sensitive layer 30. In this case, with the size of the first through hole 41 remaining unchanged, the detection sensitivity would be decreased. In contrast, in this embodiment, the first insulating layer 80 does not overlap the first through hole 41 in the direction Z perpendicular to the plane on which the substrate 10 is located, which can ensure that the first through hole 41 exposes the ion-sensitive layer 30 only, thereby ensuring the detection sensitivity.

As another feasible embodiment, FIG. 13 is another structural diagram of an ion detection device according to an embodiment of the present disclosure. As shown in FIG. 13, in one or more embodiments, the reference electrode 70 does not overlap the ion-sensitive layer 30.

In this embodiment, the pattern of the ion-sensitive layer 30 is adjusted to reserve space for disposing the reference electrode 70 so that the reference electrode 70 does not overlap the ion-sensitive layer 30 in the direction Z perpendicular to the plane on which the substrate 10 is located. That is, a spacing is provided between the reference electrode 70 and the ion-sensitive layer 30 in a direction parallel to the plane on which the substrate 10 is located, thereby ensuring the insulation between the reference electrode 70 and the ion-sensitive layer 30.

With continued reference to FIG. 13, in one or more embodiments, the reference electrode 70 and the first blocking portion 51 are located in the same layer and spaced apart from each other. In other words, during the preparation of the blocking layer 50, the preparation of the first blocking portion 51 and the reference electrode 70 is simultaneously completed. For example, a full blocking layer is first prepared, and then an etching process is used to pattern the full blocking layer to obtain both the pattern of the first blocking portion 51 and the pattern of the reference electrode 70 so that the first blocking portion 51 and the reference electrode 70 are located in the same layer and spaced apart from each other. In this manner, the preparation efficiency can be improved, and the preparation cost can be reduced.

In one or more embodiments, referring to FIG. 13, in this example, the first blocking portion 51 and the second blocking portion 52 are connected to each other and integrally formed to form the blocking structure 501, and the blocking structure 501 and the reference electrode 70 are located in the same layer and spaced apart from each other.

In one or more embodiments, the ion detection device 100 further includes a microfluidic module. The microfluidic module includes a microfluidic channel that communicates with the first through hole.

In one or more embodiments, the ion detection device may utilize a microfluidic solution to achieve the injection of the testing solution. The specific structure of the microfluidic module is not limited in the embodiment of the present disclosure and may be designed by those skilled in the art, as long as it is ensured that the microfluidic channel communicates with the first through hole 41 on the encapsulation layer 40, allowing the testing solution to enter the first through hole 41 through the microfluidic channel and contact the ion-sensitive layer 30.

Referring to FIG. 13, it is to be understood that when the ion detection device 100 includes the reference electrode 70, the microfluidic channel is further connected to the second through hole 42.

In other embodiments, the testing solution may also be dispensed onto the ion detection device using a pipette, which is not specifically limited in the embodiment of the present disclosure.

It is to be understood that one first transistor 21 corresponds to one detection pixel. The preceding embodiments are illustrated using an example in which the ion detection device is a single-pixel detection device. In other embodiments, the ion detection device may further include multiple detection pixels arranged in an array to enhance the performance of the ion detection device. A brief description is provided below, and similarities are not repeated.

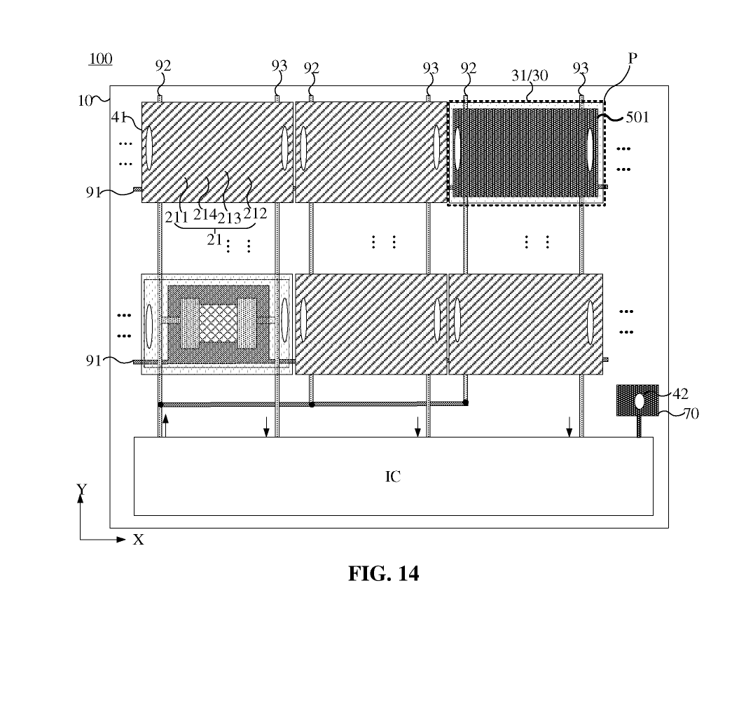

In one or more embodiments, FIG. 14 is another structural diagram of an ion detection device according to an embodiment of the present disclosure. As shown in FIG. 14, the ion detection device 100 includes multiple first transistors 21 arranged in a two-dimensional array along a first direction X and a second direction Y, where the first direction X and the second direction Y intersect and are both parallel to the plane on which the substrate 10 is located. Moreover, the ion detection device 100 further includes multiple scan lines 91, multiple bias signal lines 92, and multiple feedback signal lines 93. The multiple scan lines 91 extend along the first direction X and are arranged along the second direction Y. The multiple bias signal lines 92 and the multiple feedback signal lines 93 extend along the second direction Y and are arranged along the first direction X. First gates 214 of multiple first transistors 21 arranged side by side along the first direction X are electrically connected to the same scan line 91. First terminals (such as sources 211) of multiple first transistors 21 arranged side by side along the second direction Y are electrically connected to the same bias signal line 92. Second terminals (such as drains 212) of the multiple first transistors 21 arranged side by side along the second direction Y are electrically connected to the same feedback signal line 93.

One first transistor 21 corresponds to one detection pixel P. In one or more embodiments, the scan lines 91, the bias signal lines 92, and the feedback signal lines 93 are all coupled to a control chip IC. The control chip IC can gate the first transistors row by row through the multiple scan lines 91, provide bias signals to the first transistors 21 in the gated state through the bias signal lines 92, and receive output signals of the first transistors 21 through the feedback signal lines 93. In this manner, the control chip IC can comprehensively analyze the to-be-detected ions in the testing solution according to the output signals of the multiple first transistors 21, thereby enhancing the performance of the device.

Referring to FIG. 14, in one or more embodiments, all the bias signal lines 92 are electrically connected.

Referring to FIG. 14, when the ion detection device 100 includes multiple first transistors 21, in one or more embodiments, the ion-sensitive layer 30 includes multiple first ion-sensitive patterns 31 spaced apart. One first ion-sensitive pattern 31 corresponds to at least one first transistor 21, and the number of first ion-sensitive patterns 31 is less than or equal to the number of first transistors 21.

In one or more embodiments, FIG. 14 shows an example in which the first ion-sensitive patterns 31 are in one-to-one correspondence with the first transistors 21. In other embodiments, multiple first transistors 21 may correspond to the same first ion-sensitive pattern 31, which is not limited in the embodiment of the present disclosure.

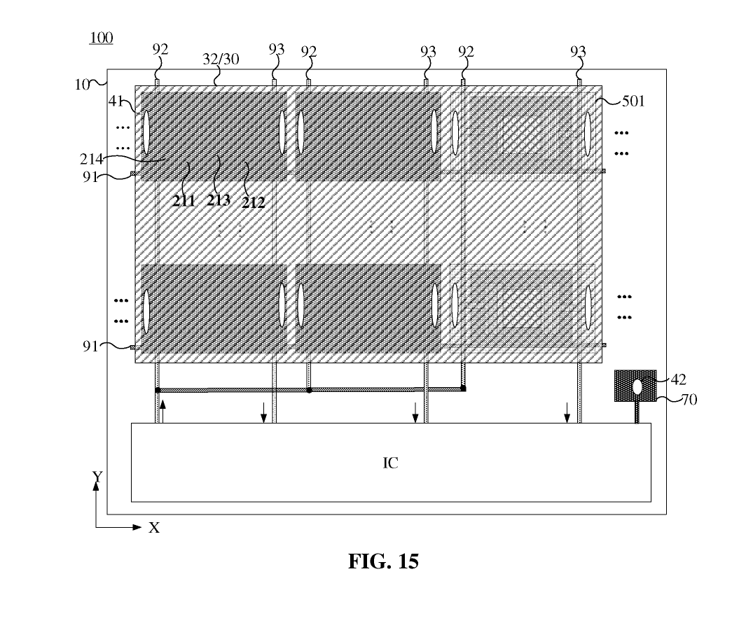

FIG. 15 is another structural diagram of an ion detection device according to an embodiment of the present disclosure. As shown in FIG. 15, in one or more embodiments, the ion-sensitive layer 30 includes one second ion-sensitive pattern 32, and all the first transistors 21 are located within the coverage range of the second ion-sensitive pattern 32 in the direction perpendicular to the plane on which the substrate 10 is located. In other words, all the first transistors 21 correspond to the same ion-sensitive pattern 32.

It is to be noted that FIGS. 14 and 15 show an example in which the ion-sensitive layer 30 does not overlap the reference electrode 70. Referring to the preceding description, in one or more embodiments, the ion-sensitive layer 30 overlaps the reference electrode 70 along the direction perpendicular to the plane on which the substrate 10 is located, and an insulating layer is disposed between the ion-sensitive layer 30 and the reference electrode 70 to ensure the insulation between the ion-sensitive layer 30 and the reference electrode 70.

Referring to FIGS. 14 and 15, when the ion detection device 100 includes the multiple first transistors 21, in one or more embodiments, each first transistor 21 corresponds to at least one first through hole 41. FIGS. 14 and 15 show an example in which each first transistor 21 corresponds to two first through holes 4. In other embodiments, each first transistor 21 may correspond to one or more first through holes 41.

Referring to FIGS. 14 and 15, when the ion detection device 100 includes multiple first transistors 21, blocking structures 501 are in one-to-one correspondence with the first transistors 21.

Referring to FIGS. 14 and 15, when including the multiple first transistors 21, the ion detection device 100 includes one reference electrode 70. The cross-sectional structure of each detection pixel P may be disposed with reference to any one of the preceding embodiments and is not repeated herein.

The preceding embodiments do not limit the scope of the present disclosure. It is to be understood by those skilled in the art that various modifications, combinations, sub-combinations, and substitutions may be made according to design requirements and other factors. Any modification, equivalent substitution, improvement or the like that is made within the spirit and principle of the present disclosure is within the scope of the present disclosure.

What is claimed is:

1. An ion detection device, comprising:
a substrate;
a circuit layer located on a side of the substrate, wherein the circuit layer comprises a first transistor;
an ion-sensitive layer located on a side of the circuit layer facing away from the substrate;
an encapsulation layer located on a side of the ion-sensitive layer facing away from the substrate, wherein the encapsulation layer is provided with a first through hole, and the first through hole exposes part of the ion-sensitive layer; and
a blocking layer located between the circuit layer and the ion-sensitive layer, wherein the blocking layer comprises a first blocking portion, and the first blocking portion overlaps the first through hole in a direction perpendicular to a plane on which the substrate is located.

2. The ion detection device according to claim 1, wherein an orthographic projection of the first blocking portion on the substrate covers an orthographic projection of the first through hole on the substrate.

3. The ion detection device according to claim 1, wherein the blocking layer further comprises a second blocking portion, and the second blocking portion overlaps the first transistor in the direction perpendicular to the plane on which the substrate is located.

4. The ion detection device according to claim 3, wherein the blocking layer comprises a blocking structure, and the blocking structure comprises the first blocking portion and the second blocking portion that are connected to each other.

5. The ion detection device according to claim 4, wherein an orthographic projection of the blocking structure on the substrate covers an orthographic projection of the first transistor on the substrate.

6. The ion detection device according to claim 1, wherein the first transistor comprises a source and a drain, and the first through hole does not overlap at least one of the source or the drain in the direction perpendicular to the plane on which the substrate is located.

7. The ion detection device according to claim 6, wherein the first through hole does not overlap the first transistor in the direction perpendicular to the plane on which the substrate is located.

8. The ion detection device according to claim 5, further comprising a dielectric layer located between the first transistor and the blocking layer;
wherein the dielectric layer is formed with a first groove, and the first groove overlaps a channel region of the first transistor in the direction perpendicular to the plane on which the substrate is located.

9. The ion detection device according to claim 8, wherein the dielectric layer comprises a first dielectric layer and a second dielectric layer, and the second dielectric layer is located between the first dielectric layer and the blocking layer; and
a thickness of the second dielectric layer is greater than a thickness of the first dielectric layer, and the first groove is located in the second dielectric layer.

10. The ion detection device according to claim 9, wherein the first groove penetrates through the second dielectric layer.

11. The ion detection device according to claim 8, wherein the first transistor comprises a source and a drain, and the first groove does not overlap the source and the drain in the direction perpendicular to the plane on which the substrate is located.

12. The ion detection device according to claim 5, wherein the first transistor comprises a first gate, an active layer, and a second gate, the first gate is located between the substrate and the active layer, and the second gate is located on a side of the active layer facing away from the substrate;
the ion detection device further comprises a dielectric layer, and the dielectric layer is located between the second gate and the blocking layer; and
the dielectric layer comprises a first via, and the blocking structure is electrically connected to the second gate through the first via.

13. The ion detection device according to claim 1, wherein the ion-sensitive layer is in direct contact with the blocking layer.

14. The ion detection device according to claim 1, wherein a material of the blocking layer comprises metal.

15. The ion detection device according to claim 1, wherein the first transistor comprises a source and a drain;
the ion detection device further comprises a first dielectric layer, and the first dielectric layer covers the source and the drain; and
the blocking layer is located on a side of the first dielectric layer facing away from the substrate.

16. The ion detection device according to claim 1, further comprising a reference electrode located on the side of the circuit layer facing away from the substrate;
wherein the encapsulation layer is further provided with a second through hole, and the second through hole exposes part of the reference electrode.

17. The ion detection device according to claim 16, wherein the reference electrode overlaps the ion-sensitive layer in the direction perpendicular to the plane on which the substrate is located; and the ion detection device further comprises a first insulating layer, and the first insulating layer is located between the reference electrode and the ion-sensitive layer.

18. The ion detection device according to claim 16, wherein the reference electrode does not overlap the ion-sensitive layer.

19. The ion detection device according to claim 18, wherein the reference electrode and the first blocking portion are located in a same layer and are spaced apart from each other.

20. The ion detection device according to claim 1, further comprising:
a microfluidic module, wherein the microfluidic module comprises a microfluidic channel, and the microfluidic channel communicates with the first through hole.
